(19) United States
(12) Patent Application Publication
(10) Pub. No.: US 2024/0250219 A1
(43) Pub. Date: Jul. 25, 2024

(54) MANUFACTURING METHOD OF ELECTRONIC DEVICE

(71) Applicant: InnoLux Corporation, Miao-Li County (TW)

(72) Inventors: Kai CHENG, Miao-Li County (TW); Fang-Ying LIN, Miao-Li County (TW); Ming-Chang LIN, Miao-Li County (TW); Tsau-Hua HSIEH, Miao-Li County (TW)

(21) Appl. No.: 18/403,510

(22) Filed: Jan. 3, 2024

(30) Foreign Application Priority Data
Jan. 19, 2023 (TW) 112102813

(51) Int. Cl. H01L 33/48; H01L 25/075; H01L 25/16

(52) U.S. Cl. CPC H01L 33/486; H01L 25/0753; H01L 25/167

(57) ABSTRACT

A manufacturing method of an electronic device includes: providing a first substrate, which has a base layer and a plurality of electronic components disposed on the base layer; adhering adhesive material to each of the plurality of electronic components; providing a target substrate, wherein the target substrate and the first substrate are separated from each other by a distance; and transferring at least part of the plurality of electronic components adhered with the adhesive material to the target substrate through a laser process, wherein at least part of the plurality of electronic components are attached to the target substrate via the adhesive material.

### CROSS-REFERENCE TO RELATED APPLICATIONS

This application claims the benefits of the Taiwan Patent Application Serial Number 112102813, filed on Jan. 19, 2023, the subject matter of which is incorporated herein by reference.

### BACKGROUND

### Field of the Disclosure

The present disclosure relates to a manufacturing method of an electronic device and, more particularly, to a manufacturing method of an electronic device capable of effectively simplifying the required steps of the manufacturing process.

### Description of Related Art

At present, in the process of using laser transfer technology to transfer and fix electronic components to the final substrate for making electronic devices, it is necessary to first transfer the electronic components from one carrier to another carrier, and then carry out the bonding related process to fix the electronic components on the final substrate. Therefore, the laser transfer process requires many steps, which causes the complexity of the manufacturing process and the reduction of the yield rate, thereby failing to meet the actual needs.

Therefore, it is desired to provide an improved manufacturing method of an electronic device so as to mitigate and/or obviate the aforementioned problems.

### SUMMARY

The present disclosure provides a manufacturing method of an electronic device, which comprises the steps of: providing a first substrate including a base layer and a plurality of electronic components disposed on the base layer; adhering adhesive material to each of the electronic components; providing a target substrate, wherein the target substrate and the first substrate are separated from each other by a distance; and transferring at least part of the electronic components adhered with the adhesive material to the target substrate through a laser process, wherein at least part of the electronic components are attached to the target substrate via the adhesive material.

The present disclosure further provides a manufacturing method of an electronic device, which comprises the steps of: providing a first substrate including a base layer and a plurality of electronic components disposed on the base layer; providing a target substrate having an adhesive layer, wherein the target substrate and the first substrate are separated from each other by a distance; and transferring at least part of the electronic components disposed on the first substrate to the target substrate through a laser process, wherein at least part of the electronic components are attached to the target substrate via the adhesive layer.

Other novel features of the disclosure will become more apparent from the following detailed description when taken in conjunction with the accompanying drawings.

### BRIEF DESCRIPTION OF DRAWINGS

FIG. 1 is a flowchart of the manufacturing method of an electronic device according to an embodiment of the present disclosure;

FIG. 2 is a schematic diagram of a first substrate provided by the manufacturing method of an electronic device according to an embodiment of the present disclosure;

FIG. 3 is a schematic diagram of making a plurality of electronic components respectively adhered with adhesive material in the manufacturing method of an electronic device according to an embodiment of the present disclosure;

FIG. 4 is a schematic diagram of a target substrate provided by the manufacturing method of an electronic device according to an embodiment of the present disclosure;

FIG. 5 is a schematic diagram of transferring and attaching an electronic component to a target substrate in the manufacturing method of an electronic device according to an embodiment of the present disclosure;

FIG. 6 is a schematic diagram of the manufacturing method of an electronic device according to an embodiment of the present disclosure, where electronic components are bonded to a target substrate through a bonding process

FIG. 7A shows an electronic device according to an embodiment of the present disclosure, wherein the adhesive material adhered to the electronic components is an anisotropic conductive paste or an anisotropic conductive film;

FIG. 7B shows an electronic device according to another embodiment of the present disclosure, wherein the adhesive material adhered to the electronic components is flux;

FIG. 8 shows the preparation of a first substrate according to an embodiment of the present disclosure;

FIG. 9 shows a schematic diagram of using a circuit substrate as a target substrate in the manufacturing method of an electronic device according to another embodiment of the present disclosure;

FIG. 10A is a schematic diagram of a first substrate provided by the manufacturing method of an electronic device according to still another embodiment of the present disclosure;

FIG. 10B is a schematic diagram of adhering adhesive material to a plurality of electronic components respectively in the manufacturing method of an electronic device according to still another embodiment of the present disclosure;

FIG. 10C is a schematic diagram of a target substrate provided by the manufacturing method of an electronic device according to still another embodiment of the present disclosure;

FIG. 10D is a schematic diagram of transferring and attaching electronic components to a target substrate in the manufacturing method of an electronic device according to still another embodiment of the present disclosure;

FIG. 10E is a schematic diagram of the bonding process and subsequent processes for making an electronic device according to still another embodiment of the manufacturing method of an electronic device;

FIG. 11 is a flowchart of the manufacturing method of an electronic device according to yet another embodiment of the present disclosure;

FIG. 12 is a schematic diagram of a target substrate provided by the manufacturing method of an electronic device according to yet another embodiment of the present disclosure;

FIG. 13 is a schematic diagram of transferring and attaching electronic components to a target substrate in the manufacturing method of an electronic device according to yet another embodiment of the present disclosure.

FIG. 14 is a schematic diagram of the manufacturing method of an electronic device according to yet another embodiment of the present disclosure, where electronic components are bonded to a target substrate through a bonding process;

FIG. 15A shows an electronic device according to yet another embodiment of the present disclosure, wherein the electronic components are bonded to a target substrate through an anisotropic conductive paste or an anisotropic conductive film; and

FIG. 15B shows an electronic device according to yet another embodiment of the present disclosure, wherein the electronic components are bonded to a target substrate through flux.

### DETAILED DESCRIPTION OF EMBODIMENT

Different embodiments of the present disclosure are provided in the following description. These embodiments are meant to explain the technical content of the present disclosure, but not meant to limit the scope of the present disclosure. A feature described in an embodiment may be applied to other embodiments by suitable modification, substitution, combination, or separation.

It should be noted that, in the present specification, when a component is described to “comprise”, “have”, “include” an element, it means that the component may include one or more of the elements, and the component may include other elements at the same time, and it does not mean that the component has only one of the element, except otherwise specified.

Moreover, in the present specification, the ordinal numbers, such as “first” or “second”, are only used to distinguish a plurality of elements having the same name, and it does not means that there is essentially a level, a rank, an executing order, or an manufacturing order among the elements, except otherwise specified. The ordinal numbers of the elements in the specification may not be the same in claims. For example, a “second” element in the specification may be a “first” element in the claims.

In the present specification, except otherwise specified, the feature A “or” or “and/or” the feature B means only the existence of the feature A, only the existence of the feature B, or the existence of both the features A and B. The feature A “and” the feature B means the existence of both the features A and B.

Moreover, in the present specification, the terms, such as “top”, “upper”, “bottom”, “front”, “back”, or “middle”, as well as the terms, such as “on”, “above”, “over”, “under”, “below”, or “between”, are used to describe the relative positions among a plurality of elements, and the described relative positions may be interpreted to include their translation, rotation, or reflection.

Furthermore, the terms recited in the specification and the claims such as “above”, “over”, “on”, “below”, or “under” are intended that an element may not only directly contacts other element, but also indirectly contact the other element.

Furthermore, the term recited in the specification and the claims such as “connect” is intended that an element may not only directly connect to other element, but also indirectly connect to other element. On the other hand, the terms recited in the specification and the claims such as “electrically connect” and “couple” are intended that an element may not only directly electrically connect to other element, but also indirectly electrically connect to other element.

In the present specification, except otherwise specified, the terms (including technical and scientific terms) used herein have the meanings generally known by a person skilled in the art. It should be noted that, except otherwise specified in the embodiments of the present disclosure, these terms (for example, the terms defined in the generally used dictionary) should have the meanings identical to those skilled in the art, the background of the present disclosure or the context of the present specification, and should not be read by an ideal or over-formal way.

In the specification, an electronic device may include a display device, a backlight device, an antenna device, a sensing device or a tiled device, but it is not limited thereto. The electronic device may be a bendable or flexible electronic device. The display device may be a non-self-luminous display device or a self-luminous display device. The antenna device may be a liquid crystal type antenna device or a non-liquid crystal type antenna device. The sensing device may be such a sensing device for sensing capacitance, light, thermal energy or ultrasonic waves, but it is not limited thereto. Electronic components may include passive components and active components, such as capacitors, resistors, inductors, diodes, transistors, or semiconductor chips. The diodes may include light emitting diodes or photodiodes. The light emitting diodes may for example, include organic light emitting diodes (OLEDs), sub-millimeter light emitting diodes (mini LEDs), micro light emitting diodes (micro LEDs) or quantum dot light emitting diodes (quantum dot LEDs), but it is not limited thereto. The tiled device may be, for example, a display tiled device or an antenna tiled device, but it is not limited thereto. It should be noted that the electronic device may be any permutation and combination of the aforementioned, but it is not limited thereto. In the following, the display device is used as an electronic device or a tiled device to illustrate the content of the present disclosure, but the present disclosure is not limited thereto.

FIG. 1 is a flowchart of the manufacturing method of an electronic device according to an embodiment of the present disclosure. As shown, the flowchart of the manufacturing method of an electronic device includes: step S11 for providing a first substrate, in which the first substrate has a base layer and a plurality of electronic components disposed on the base layer; step S13 for making the plurality of electronic components adhered with adhesive material; step S15 for providing a target substrate, in which the target substrate and the first substrate are separated from each other by a distance; step S17 for transferring at least part of the plurality of electronic components adhered with adhesive material to the target substrate through a laser process, in which at least part of the plurality of electronic components are attached to the target substrate via the adhesive material; and step S19 for bonding at least part of the plurality of electronic components to the target substrate by a bonding process. In the present disclosure, the electronic component may be a light emitting diode (LED), a semiconductor chip, etc., and the electronic device is a device corresponding to the function of the electronic component. For example, when the electronic component is a micro light emitting diode, the electronic device is a micro light emitting diode display, while this is only an example but not a limitation. Each step of the manufacturing method of an electronic device disclosed in the present disclosure is described below.

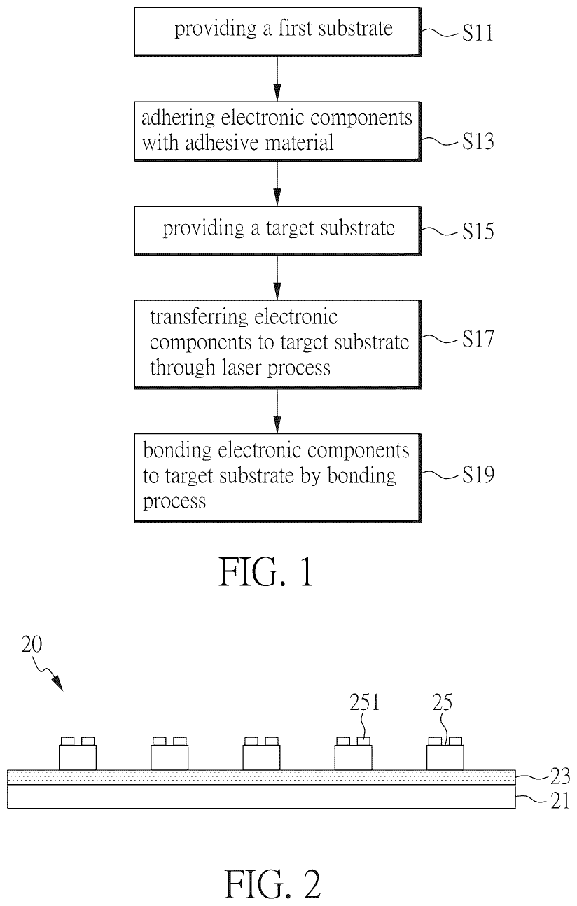

FIG. 2 is a schematic diagram of the first substrate 20 provided in step S11 of the manufacturing method of an electronic device of this embodiment, wherein the first substrate 20 has a base layer 21 and a plurality of electronic components 25 disposed on the base layer 21. The base layer 21 may be, for example, an epitaxial wafer, a glass substrate, a plastic substrate, a metal substrate, a sapphire substrate or a quartz substrate or any substrate capable of carrying electronic components. The electronic components 25 are, for example, disposed on the base layer 21 through an interposer 23. The interposer 23 may include organic materials or inorganic materials, such as photoresist, polyimide, and glue material with viscosity after curing, such as silicon, glue on tape, UV photosensitive glue, AB glue, etc., or a weakened structure (such as a tether structure that is temporarily fixed mechanically and may be broken after pressurization), while this is only an example but not a limitation. The side of the electronic component 25 opposite to the base layer 21 is provided with at least one connection pad 251 for providing electrical connection of the electronic component 25.

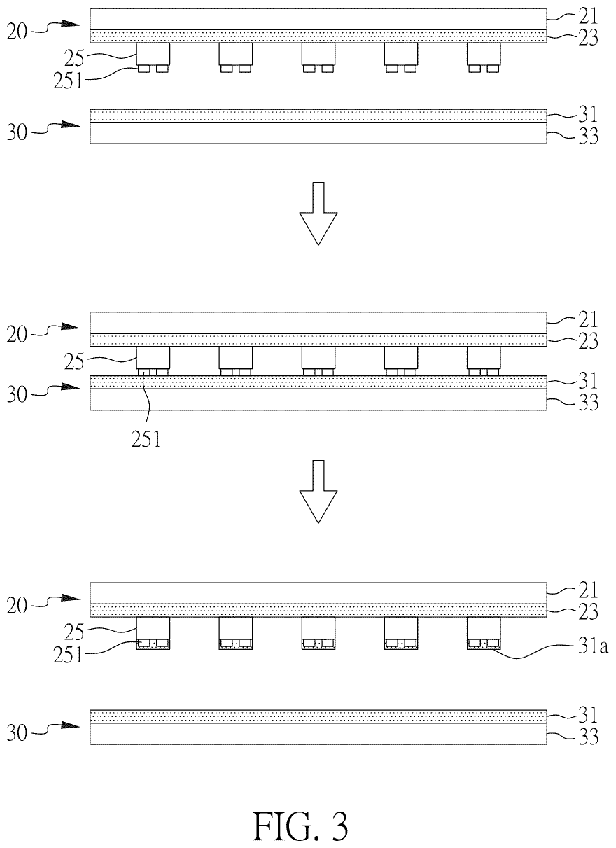

FIG. 3 shows a schematic diagram of making a plurality of electronic components 25 respectively adhered with adhesive material to in step S13 of the manufacturing method of the electronic device of this embodiment. In step S13, a second substrate 30 is first provided for carrying out the operation of adhering the adhesive material to the first substrate 20. The second substrate 30 has an adhesive layer 31 disposed on a carrier 33. The carrier 33 may be, for example, a glass substrate, a plastic substrate, a metal substrate, a sapphire substrate or a quartz substrate, and the adhesive layer 31 includes, for example, a flux, an anisotropic conductive paste (ACP) or an anisotropic conductive film (ACF), while this is only an example but not a limitation, wherein the flux is a non-conductive adhesive material, and the anisotropic conductive paste or anisotropic conductive film is adhesive material with features of vertical (Z axis) electrical conduction and horizontal plane (X axis, Y axis) insulation. For the operation of adhering the adhesive material, the side of the first substrate 20 with the plurality of electronic components 25 faces the side of the second substrate 30 with the adhesive layer 31, and the plurality of electronic components 25 are in contact with the adhesive layer 31 to be respectively adhered with the adhesive material 31a. After being adhered with the adhesive material 31a, the plurality of electronic components 25 are separated from the second substrate 30, so that part of the adhesive material 31a is attached to the electronic components 25. In more detail, the adhesive material 31a is adhered to the connection pad 251 of the electronic component 25.

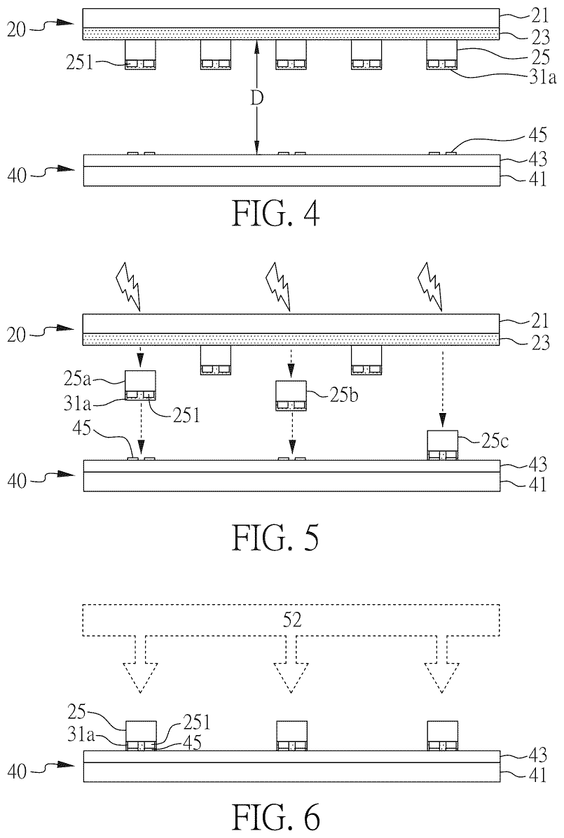

FIG. 4 is a schematic diagram of the target substrate 40 provided in step S15 of the manufacturing method of an electronic device of this embodiment, wherein the target substrate 40 is such a substrate for setting electronic components 25 and other related circuits. In this embodiment, the target substrate 40 is a thin film transistor (TFT) substrate, and the electronic component 25 is a light emitting diode (LED). The target substrate 40 includes a substrate 41, a circuit layer 43 formed on the substrate 41, and a plurality of connection portions 45 disposed on the circuit layer 43 for bonding the electronic components 25. The material of the substrate 41 may be the same as or different from that of the carrier, and will not be repeated here. The circuit layer 43 may include thin film transistors, metal layers and insulating layers. In this step, in order to carry out the operation of laser transfer, the side of the first substrate 20 with a plurality of electronic components 25 obtained in step 13 faces the side of the target substrate 40 with the circuit layer 43, and the target substrate 40 and the first substrate 30 are separated from each other by a distance D, wherein the distance D may be greater than 0 μm and smaller than or equal to 200 μm or, further, the distance D may be greater than 0 μm and smaller than or equal to 150 μm, and the distance D refers to such a distance between the surfaces of the first substrate 30 and the target substrate 40 that face to each other, that is, the distance from the surface of the interposer 23 of the first substrate 30 away from the base layer 21 to the surface of the circuit layer 43 of the target substrate 40 away from the substrate 41.

FIG. 5 is a schematic diagram of transferring and attaching the electronic component 25 to the target substrate 40 in step S17 in the manufacturing method of an electronic device of this embodiment. In this step, as shown, a laser process performs laser bombardment on a partial area of the interposer 23 of the first substrate 30, so as to at least part of the plurality of electronic components 25 adhered with adhesive material 31a on the first substrate 30 (for example, electronic components 25a, 25b, 25c as shown in FIG. 5) are transferred to the target substrate 40. That is, the interposer 23 bombarded by the laser will lose its viscosity, generate gas due to sintering, or destroy the weakened structure, and the electronic components 25 (25a, 25b, 25c) are detached from the base layer 21 and dropped onto the target substrate 40, so that at least part of the plurality of electronic components 25 (25a, 25b, 25c) are attached to the target substrate 40 through the adhered adhesive material 31a, wherein, during the transfer process, the connection pads 251 of the electronic components 25 are aligned with the corresponding connection portions 45 of the target substrate 40, so that the electronic components 25 may be electrically connected to the circuit layer 43 of the target substrate 40. In the present disclosure, the wavelength of the laser beam used in the laser process may be the laser beam in the UV band or the laser beam in the visible band (such as 343 nm, 355 nm or 532 nm), but the present disclosure is not limited thereto.

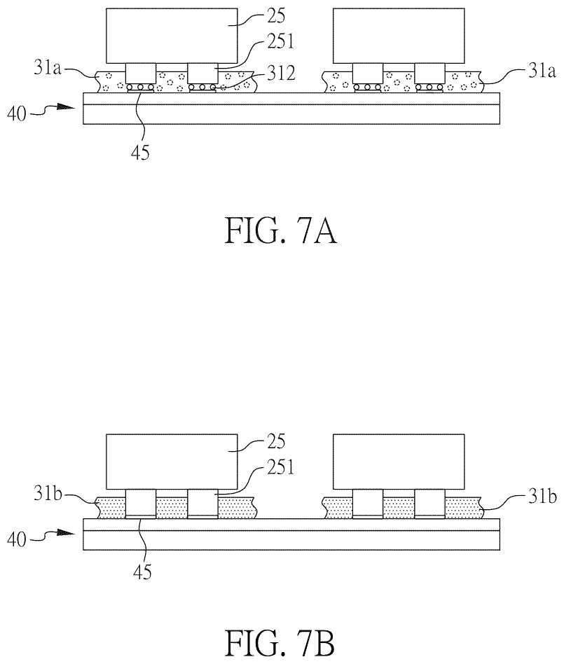

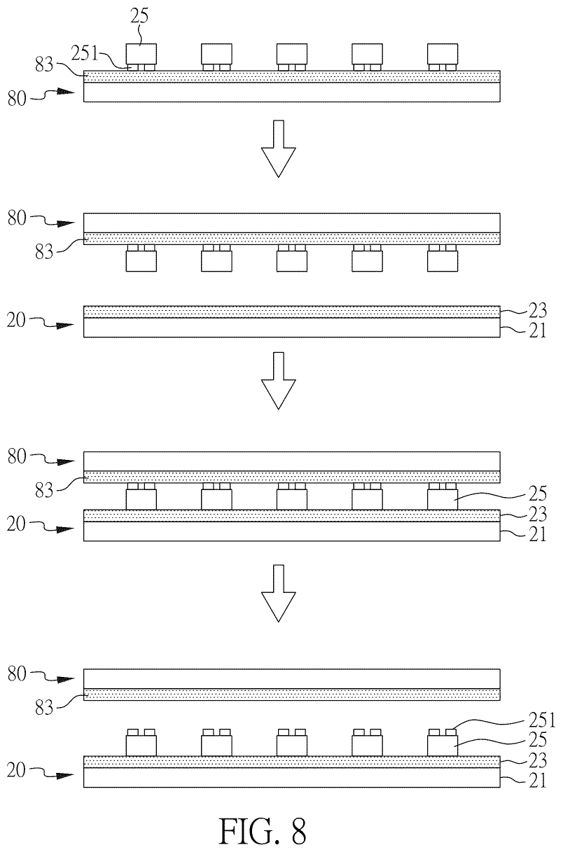

FIG. 6 is a schematic diagram of bonding the electronic components 25 to the target substrate 40 through a bonding process 52 in step S19 of the manufacturing method of an electronic device of this embodiment. In this step, as shown, the bonding process 52 may include irradiation (such as applying laser), heating or pressurization, or a combination thereof, so as to bond the connection pad 251 of the electronic component 25 to the connection portion 45 of the target substrate, thereby bonding the electronic component 25 to the target substrate 40. After the bonding process 52, the manufacture of the electronic device of the present disclosure can be completed. FIG. 7A shows a schematic diagram of an example in which the electronic component 25 is bonded to the target substrate 40 after the bonding process is completed. In this example, the adhesive material 31a adhered on the electronic component 25 is anisotropic conductive paste or anisotropic conductive film, wherein the connection pad 251 of the electronic component 25 is bonded to the connection portion 45 of the target substrate 40 through part of the adhesive material 31a of the adhesive layer 31. Because the adhesive material 31a is anisotropic conductive paste or anisotropic conductive film, the conductive particles 312 between the connection pad 251 and the connection portion 45 have the feature of vertical electrical conduction, and thus the connection pad 251 and the connection portion 45 may be electrically connected. However, for different connection pads 251 of the same electronic component 25 or for different connection portions 45 of the target substrate 40, because the conductive particles 312 of the anisotropic conductive paste or anisotropic conductive film have the feature of horizontal planar insulation, it will not cause the short circuit problem due to wrong electrical connection. Moreover, FIG. 7A shows that only one electronic component 25 is bonded to the target substrate 40 in part of the adhesive material 31a, but the present disclosure is not limited thereto. In actual applications, based on the conductive particles of the anisotropic conductive paste or the anisotropic conductive film having the feature of horizontal planar insulation, more than one electronic component 25 may be bonded to the target substrate 40 in part of the adhesive material 31a without causing a short circuit between electronic components 25. FIG. 7B shows a schematic diagram of another embodiment in which an electronic component 25 is bonded to a target substrate 40 after the bonding process is completed. In this example, the adhesive material 31b adhered to the electronic component 25 is flux, wherein the connection pad 251 of the electronic component 25 is bonded to the connection portion 45 of the target substrate 40, and the adhesive material 31b may remove the oxide on the connection portion 45 or the connection pad 251 during the bonding process, so that the connection pad 251 and the connection portion 45 are electrically connected to achieve bonding of the electronic device 25 and the target substrate 40.

In addition, in order to provide the first substrate 20, FIG. 8 shows the preparation of the first substrate 20 provided in step S11, which first provides a carrier 80 that has a plurality of electronic components 25, and the surface of the electronic component 25 with connection pad 251 faces the carrier 80 and is disposed on the carrier 80 through the interposer 83. The interposer 83 on the carrier 80 may include organic material or inorganic material, such as photoresist, polyimide, adhesive material (such as silicon, UV photosensitive adhesive, or any material that is sticky after curing) or a weakened structure (such as a tether structure that is temporarily fixed mechanically and may be broken after pressurization). Then, a plurality of electronic components 25 are transferred from the carrier 80 to the base layer 21 of the first substrate 20. As shown in FIG. 8, in the transfer process, the surface of the carrier 80 with the electronic components 25 is made to face the base layer 21 of the first substrate 20. Then, the end of the electronic component 25 of the carrier 80 away from the carrier 80 is made to contact the interposer 23 on the base layer 21 of the first substrate 20. Then, viscosity of the adhesive material of the interposer 83 on the carrier 80 is reduced by, for example, lighting or other viscosity reduction methods, or the weakened structure of the interposer 83 is broken through pressurization. Accordingly, the carrier 80 can be removed to achieve the purpose of transferring the electronic component 25 to the base layer 21 of the first substrate 20.

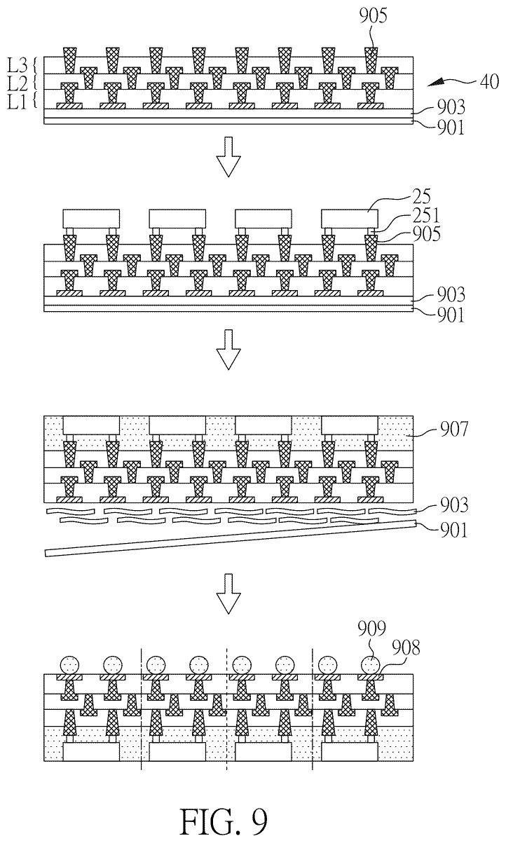

Moreover, the target substrate 40 provided in step S15 may also be a circuit substrate. FIG. 9 shows a schematic diagram of the manufacture of an electronic device using a circuit substrate as the target substrate 40 according to another embodiment of the present disclosure. This embodiment relates to a redistribution layer first (RDL-first) process, wherein the electronic component 25 is a semiconductor chip, and the target substrate 40 is a circuit substrate with a plurality of redistribution layers (RDLs). For example, in this embodiment, the target substrate 40 may include a carrier 901, a release layer 903, a first redistribution layer L1, a second redistribution layer L2 and a third redistribution layer L3, and has a plurality of bonding electrodes 905 disposed in the third redistribution layer L3 of the upper layer, and the electronic component 25 is transferred and attached to the target substrate 40 through the aforementioned steps S11 to S19. The connection pad 251 of the electronic component 25 is aligned and electrically connected to the corresponding bonding electrode 905 of the target substrate 40. After transferring the electronic components 25, as shown in FIG. 9, a sealant layer 907 may be formed on the surface of the third redistribution layer L3 of the target substrate 40 away from the second redistribution layer L2, and the carrier 901 and the release layer 903 of the target substrate 40 may be removed 901. After that, solder balls 909 are formed on the conductive pads 908 of the first redistribution layer L1, so as to provide a plurality of single-chip packages after performing a dicing process or a multi-chip package without dicing. In the present disclosure, the semiconductor chip may include a low noise amplifier (LNA), a low-loss filter, a power amplifier, a baseband circuit, a power management integrated circuit (PMIC), memory, micro electro mechanical systems (MEMS) device, integrated circuit, other suitable active components, passive components or a combination thereof, but the present disclosure is not limited thereto.

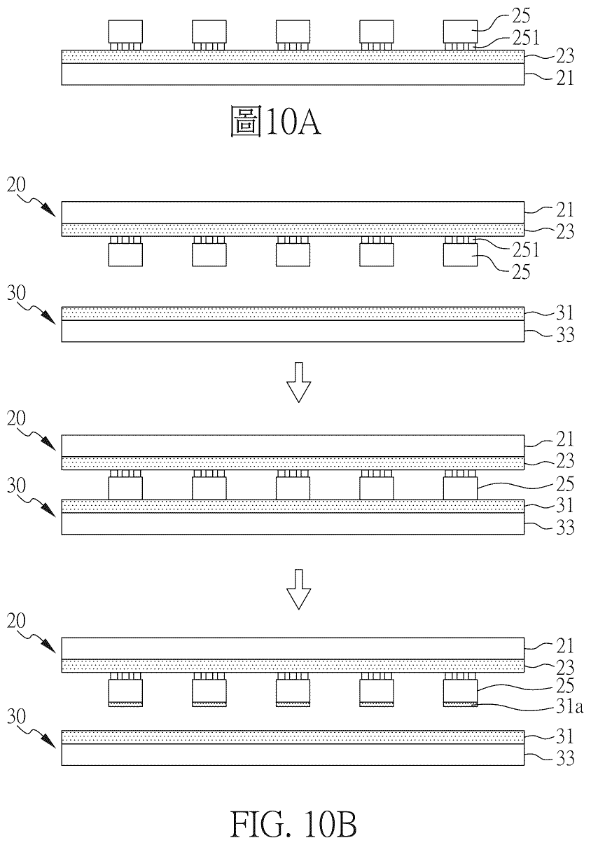

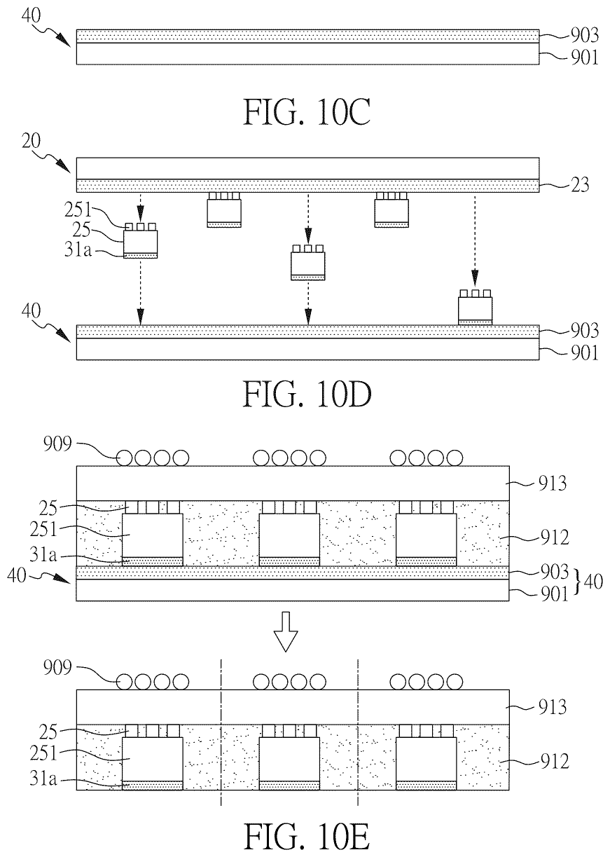

In addition, FIG. 10A to FIG. 10E schematically illustrate an embodiment of the manufacture of an electronic device according to a chip-first process. FIG. 10A is a schematic diagram of a first substrate 20 provided by step S11 of the manufacturing method of an electronic device according to still another embodiment of the present disclosure, wherein the first substrate 20 has a base layer 21 and a plurality of electronic components 25 disposed on the base layer 21, and the electronic component 25 with the surface having connection pads 251 is disposed on the base layer 21 through the interposer 23. In this embodiment, the electronic component 25 is a semiconductor chip. FIG. 10B is a schematic diagram of making a plurality of electronic components 25 respectively adhered with adhesive material in step S13 in this embodiment. First, a second substrate 30 is provided for the operation of adhering adhesive material to the first substrate 20. The second substrate 30 has an adhesive layer 31 disposed on a carrier 33, and a plurality of electronic components 25 contact the adhesive layer 31 with surfaces opposite to the connection pads 251 so as to be respectively adhered with the adhesive material 31a. After being adhered with the adhesive material 31a, the plurality of electronic components 25 are separated from the second substrate 30, so that part of the adhesive material 31a is adhered to the electronic components 25.

FIG. 10C is a schematic diagram of the target substrate provided in step S15 of the manufacturing method of an electronic device of this embodiment, wherein the target substrate 40 includes a carrier 901, and a release layer 903 arranged on the carrier 901. FIG. 10D is a schematic diagram of transferring and attaching the electronic component 25 to the target substrate 40 in step S17 of the manufacturing method of the electronic device of this embodiment. In this step, as shown in FIG. 10D, a laser process is used to perform laser bombardment on a partial area of the interposer 23 of the first substrate 20, so as to transfer at least part of the plurality of electronic components 25 adhered with the adhesive material 31a on the first substrate 20 to the target substrate 40, while the electronic component 25 is attached to the release layer 903 of the target substrate 40 by the adhesive material 31a adhered to the surface of the electronic component 25 opposite to the connection pads 251.

FIG. 10E shows the bonding process of step S19 and its subsequent process in the manufacturing method of an electronic device of this embodiment, wherein at least part of the plurality of electronic components 25 has been bonded to the target substrate 40. Then, a dielectric layer 912 is formed on the release layer 903, and the height of the dielectric layer 912 is approximately equal to the total height of the electronic component 25 and the connection pad 251. Then, a redistribution layer 913 is arranged on the dielectric layer 912, and solder balls 909 are formed on the redistribution layer 912, so that the solder balls 909 and the corresponding connection pads 251 may be electrically connected through the conductors (not shown) in the redistribution layer 913. After that, the carrier 901 and the release layer 903 of the target substrate 40 are removed, so as to provide a plurality of single-chip packages after performing a dicing process or provide a multi-chip package without dicing.

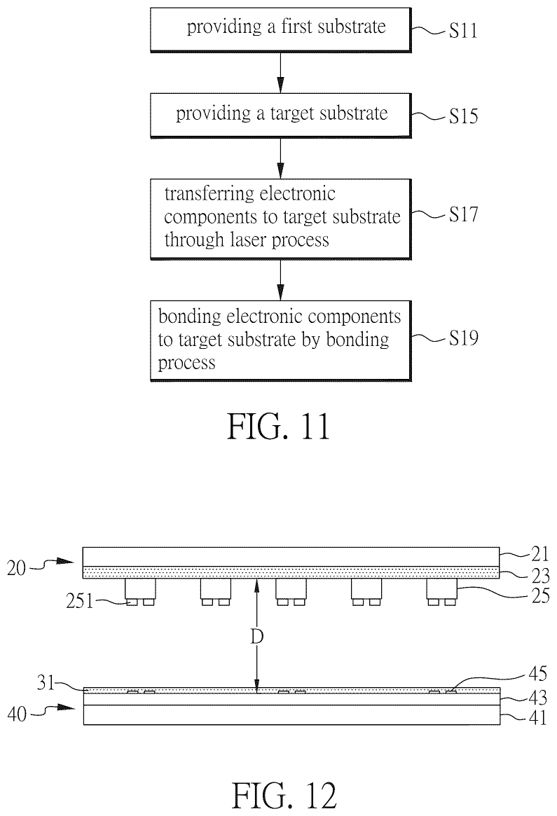

FIG. 11 is a flowchart of the manufacturing method of an electronic device according to another embodiment of the present disclosure. As shown, the flowchart of the manufacturing method of an electronic device of this embodiment is similar to that of the embodiment of FIG. 1, except that it does not have step S13 and the target substrate provided in step S15 has an adhesive layer, so that only the differences will be described below.

FIG. 12 is a schematic diagram of the target substrate 40 provided in step S15 of the manufacturing method of an electronic device of this embodiment. The step of providing the target substrate in this embodiment includes: providing a second substrate 41; and forming an adhesive layer 31 on the second substrate 41, wherein the second substrate 41 may be further formed with a circuit layer 43, and a plurality of connection portions 45 disposed on the circuit layer 43 for bonding the electronic components 25. Therefore, as shown, the target substrate 40 of this embodiment is similar to the target substrate 40 of the embodiment of FIG. 1, except that it further has an adhesive layer 31 that is disposed on the circuit layer 43 and covers the connection portions 45 on the circuit layer 43. The adhesive layer includes, for example, a flux, an anisotropic conductive paste (ACP), or an anisotropic conductive film (ACF), while this is only an example but not a limitation. In this step, in order to carry out the operation of laser transfer, the side of the first substrate 20 with a plurality of electronic components 25 provided in step 11 faces the side of the target substrate 40 with the circuit layer 43 and the adhesive layer 31, and the target substrate 40 and the first substrate 30 are separated by a distance D, where the distance D may be greater than 0 μm and smaller than or equal to 200 μm. Alternatively, furthermore, the distance D may be greater than 0 μm and smaller than or equal to 150 um, where the distance D refers to the distance between the surface of the interposer 23 of the first substrate 30 away from the base layer 21 and the surface of the circuit layer 43 of the target substrate 40 away from the substrate 41.

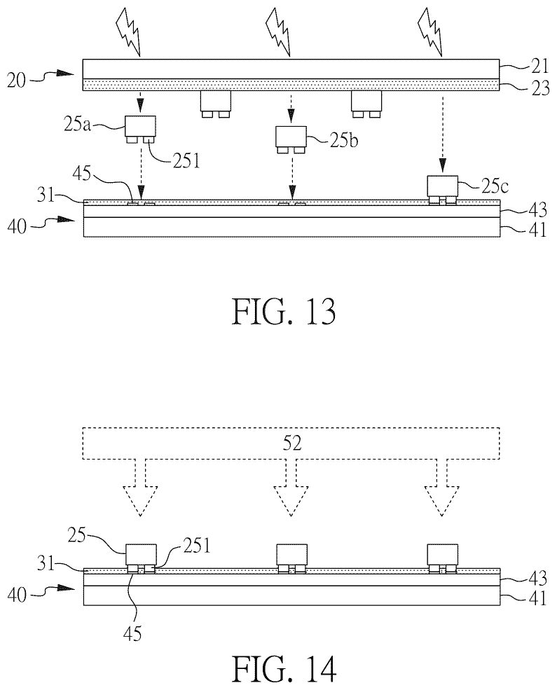

FIG. 13 is a schematic diagram of transferring and attaching the electronic component 25 to the target substrate 40 in step S17 of the manufacturing method of an electronic device of the present embodiment. In this step, as shown, a laser process is used to perform laser bombard on a partial area of the interposer 23 of the first substrate 20, so as to transfer at least part of the plurality of electronic components 25 on the first substrate 20 (such as the electronic components 25a, 25b, 25c shown in FIG. 13) to the target substrate 40. That is, after the laser bombardment, the electronic components 25 (25a, 25b, 25c) are detached from the base layer 21 and fall onto the target substrate 40 to be fixed by the adhesive material of the adhesive layer 31, so as to attach at least part of the plurality of electronic components 25 (25a, 25b, 25c) on the target substrate 40, wherein, in the transfer process, the connection pads 251 of the electronic component 25 are aligned with the corresponding connection portions 45 of the target substrate 40, so that the electronic component 25 can be electrically connected to the circuit layer 43 of the target substrate 40.

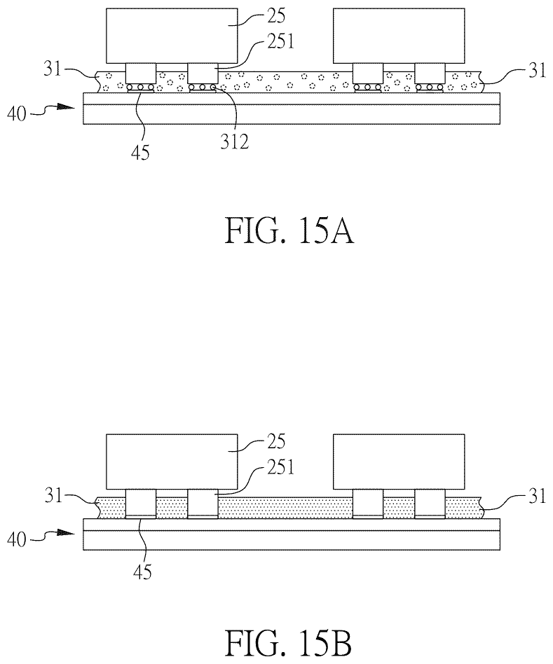

FIG. 14 is a schematic diagram illustrating that the electronic component 25 is bonded to the target substrate 40 through a bonding process 52 in the manufacturing method of an electronic device of this embodiment. In this step, as shown, the bonding process 52 may include light irradiation, heating, pressurization, or a combination thereof, so as to bond the connection pads 251 of the electronic component 25 to the connection portions 45 of the target substrate 40, thereby bonding the electronic component 25 to the target substrate 40. After this bonding process 52, the manufacture of the electronic device of the present disclosure can be completed. FIG. 15A is a schematic diagram of an example in which one or more electronic components 25 are bonded to the target substrate 40 after the bonding process is completed. In this example, the adhesive material of the adhesive layer 31 is anisotropic conductive paste or anisotropic conductive film, wherein the connection pads 251 of the electronic component 25 are bonded to the connection portions 45 of the target substrate 40 via the adhesive material of the adhesive layer 31. Because the adhesive material is anisotropic conductive paste or anisotropic conductive film, the conductive particles 312 between the connection pad 251 and the connection portion 45 have the feature of vertical electrical conduction, and thus the connection pad 251 and the connection portion 45 may be electrically connected. However, for different connection pads 251 of the same electronic component 25 or for different connection portions 45 of the target substrate 40 or even between different electronic components, because the conductive particles 312 of the anisotropic conductive paste or anisotropic conductive film have the feature of horizontal planar insulation, it will not cause the short circuit problem due to wrong electrical connection. FIG. 15B shows a schematic diagram of another example in which one or more than one electronic components 25 are bonded to the target substrate 40 after the bonding process is completed. In this example, the adhesive material of the adhesive layer 31 is flux, wherein the connection pads 251 of the electronic component 25 are bonded to the connection portions 45 of the target substrate 40, and the adhesive material of the adhesive layer 31 may remove the oxide on the connection portions 45 or the connection pads 251 during the bonding process, so that the connection pads 251 are electrically connected to the connection portions 45, thereby achieving the bonding of the electronic components 25 and the target substrate 40.

From the above description, it can be known that, by making the electronic components adhered with adhesive material, the present disclosure may directly transfer the electronic components to the target substrate for being attached to the target substrate via the adhesive material, thereby effectively simplifying the required steps of the manufacturing process.

As long as the features of the various embodiments disclosed in the present disclosure do not violate the spirit of the present disclosure or conflict with each other, they can be mixed and matched arbitrarily.

The aforementioned specific embodiments should be construed as merely illustrative, and not limiting the rest of the present disclosure in any way.

1. A manufacturing method of an electronic device, comprising the steps of:
providing a first substrate including a base layer and a plurality of electronic components disposed on the base layer;
adhering adhesive material to each of the electronic components;
providing a target substrate, wherein the target substrate and the first substrate are separated from each other by a distance; and
transferring at least part of the electronic components adhered with the adhesive material to the target substrate through a laser process, wherein at least part of the electronic components are attached to the target substrate via the adhesive material.

2. The manufacturing method of an electronic device as claimed in claim 1, wherein the base layer is an epitaxial wafer.

3. The manufacturing method of an electronic device as claimed in claim 1, wherein the step of adhering adhesive material to each of the electronic components includes:
providing a second substrate having an adhesive layer; contacting the electronic components with the adhesive layer; and separating the electronic components from the second substrate.

4. The manufacturing method of an electronic device as claimed in claim 1, wherein the distance is greater than 0 μm and smaller than or equal to 200 μm.

5. The manufacturing method of an electronic device as claimed in claim 4, wherein the distance is greater than 0 μm and smaller than or equal to 150 μm.

6. The manufacturing method of an electronic device as claimed in claim 1, wherein the adhesive material includes a flux, an anisotropic conductive paste, or an anisotropic conductive film.

7. The manufacturing method of an electronic device as claimed in claim 1, further comprising a bonding process for bonding the at least part of the electronic components to the target substrate.

8. The manufacturing method of an electronic device as claimed in claim 7, wherein the bonding process includes light irradiation, heating or pressurization, or a combination thereof.

9. The manufacturing method of an electronic device as claimed in claim 1, wherein the step of providing a first substrate further includes providing a carrier with the electronic components; and transferring the electronic components from the carrier to the base layer.

10. The manufacturing method of an electronic device as claimed in claim 1, wherein the target substrate is a thin film transistor substrate, and the electronic components are light emitting diodes.

11. The manufacturing method of an electronic device as claimed in claim 1, wherein the target substrate is a circuit substrate, and the circuit substrate includes a redistribution layer.

12. The manufacturing method of an electronic device as claimed in claim 11, wherein the electronic component is a semiconductor chip.

13. A manufacturing method of an electronic device, comprising the steps of:
providing a first substrate including a base layer and a plurality of electronic components disposed on the base layer;
providing a target substrate having an adhesive layer, wherein the target substrate and the first substrate are separated from each other by a distance; and
transferring at least part of the electronic components disposed on the first substrate to the target substrate through a laser process, wherein at least part of the electronic components are attached to the target substrate via the adhesive layer.

14. The manufacturing method of an electronic device as claimed in claim 13, wherein the base layer is an epitaxial wafer.

15. The manufacturing method of an electronic device as claimed in claim 13, wherein the step of providing a target substrate includes: providing a second substrate; and forming an adhesive layer on the second substrate.

16. The manufacturing method of an electronic device as claimed in claim 13, wherein the distance is greater than 0 μm and smaller than or equal to 200 μm.

17. The manufacturing method of an electronic device as claimed in claim 13, wherein the adhesive layer has adhesive material including a flux, an anisotropic conductive paste, or an anisotropic conductive film.

18. The manufacturing method of an electronic device as claimed in claim 13, further comprising a bonding process for bonding the at least part of the electronic components to the target substrate.

19. The manufacturing method of an electronic device as claimed in claim 18, wherein the bonding process includes light irradiation, heating, pressurization, or a combination thereof.

20. The manufacturing method of an electronic device as claimed in claim 13, wherein the step of providing a first substrate further includes providing a carrier with the electronic components; and transferring the electronic components from the carrier to the base layer.
